(19) United States
(12) Patent Application Publication
(10) Pub. No.: US 2015/0372189 A1
(43) Pub. Date: Dec. 24, 2015

(54) III NITRIDE SEMICONDUCTOR LIGHT EMITTING DEVICE

(71) Applicant: Dowa Electronics Materials Co., Ltd., Tokyo (JP)

(72) Inventor: Tetsuya MATSUURA, Akita-shi (JP)

(73) Assignee: Dowa Electronics Materials Co., Ltd., Tokyo (JP)

(21) Appl. No.: 14/763,044

(22) PCT Filed: Nov. 28, 2013
(86) PCT No.: PCT/JP2013/007011

§ 371 Date: Jul. 23, 2015

(30) Foreign Application Priority Data
Jan. 30, 2013 (JP) 2013-015120

(51) Int. Cl. H01L 33/06; H01L 33/32

(52) U.S. Cl. CPC H01L 33/06; H01L 33/32

(57) ABSTRACT

To provide a III nitride semiconductor light emitting device in which the formation of cracks in an active layer is suppressed and the light output power is improved, a III nitride semiconductor light emitting device has an n-type cladding layer, an active layer, and a p-type cladding layer in order. The active layer has a multiple quantum-well structure in which barrier layers made of Al_{X}Ga_{1-X}N and well layers are alternately stacked. The Al content X of the barrier layers is larger as the barrier layer is closer to a first barrier layer on the n-type cladding layer side and a second barrier layer on the p-type cladding layer side with reference to one or more of intermediate barrier layers that have the lowest Al content X min of the intermediate barrier layers.

### TECHNICAL FIELD

This disclosure relates to a III nitride semiconductor light emitting device.

### BACKGROUND

III nitride semiconductors made of compounds in which N is combined with Al, Ga, In, and the like are wide bandgap semiconductors having a direct transition band structure and are materials expected to be applied in wide fields. In particular, light emitting devices using a III nitride semiconductor for an active layer can cover from deep ultraviolet light of 200 nm to a visible light range by adjusting the content ratio of the Group III element. Such devices are positively put to practice use in various kinds of light sources.

A typical III nitride semiconductor light emitting device can be obtained by sequentially forming an n-type cladding layer, an active layer, and a p-type cladding layer, on a substrate of sapphire or the like with a buffer layer therebetween, and forming an n-side electrode electrically connected to the n-type cladding layer and a p-side electrode electrically connected to the p-type cladding layer. For the active layer, a multiple quantum well (MQW) structure is used in which barrier layers made of a III nitride semiconductor and well layers are alternately stacked.

Here, JP 2003-115642 A (PTL 1) discloses a short wavelength light emitting device (380 nm or less) having an active layer with a MQW structure in which Al_{X}Ga_{1-X}N barrier layers and Al_{y}Ga_{1-y}N well layers are alternately stacked. As an example of such a device, PTL 1 (Example 15) describes a structure including an active layer constituted from five well layers each interposed between adjacent two layers of six barrier layers, in which the Al content y of the well layers is 0.05, the Al content x of the bottom and top layers of the barrier layers is 0.15, and the Al content x of the four barrier layers therebetween is 0.10.

### CITATION LIST

### Patent Literature

PTL 1: JP 2003-115642 A

### SUMMARY

### Technical Problem

In recent years, III nitride semiconductor light emitting devices have attracted attention as light emitting devices that can be widely used in the fields of sterilization, water purification, medical treatment, illumination, high-density optical recording, and the like, and they are required to have higher light output power. However, the studies made by the inventor of this disclosure revealed that conventional III nitride semiconductor light emitting devices including one disclosed in PTL 1 had room for improvement in achieving higher light output power. In addition, a III nitride semiconductor device having cracks in the active layer is unsuitable as a light emitting device, since the formation of cracks in the active layer would cause a breakdown of the device. Accordingly, the improvement in light output power is a challenge to be addressed only provided that such cracks are not formed.

In view of the above challenge, it could be helpful to provide a III nitride semiconductor light emitting device in which the formation of cracks in an active layer is suppressed and the light output power is improved.

### Solution to Problem

A III nitride semiconductor light emitting device of this disclosure that makes it possible to achieve the above objective is a III nitride semiconductor light emitting device having an active layer between an n-type cladding layer and a p-type cladding layer, wherein the active layer has a multiple quantum-well structure including three or more barrier layers made of Al_{X}Ga_{1-X}N (0≦X<1) including a first barrier layer on the n-type cladding layer side, a second barrier layer on the p-type cladding layer side, and one or more intermediate barrier layers located between the first and second barrier layers; and two or more well layers made of a III nitride semiconductor interposed between the barrier layers; the Al content X of the barrier layers is larger as the barrier layer is closer to the first barrier layer and the second barrier layer with reference to one or more of the intermediate barrier layers having the lowest Al content X min of the intermediate barrier layers; and an Al content X1 of the first barrier layer, an Al content X2 of the second barrier layer, and the Xmin satisfy the relations represented by the Equation (1) and Equation (2):

X2+0.01≦X1 (1), and

Xmin+0.03≦X2 (2).

It is preferred that the n-type cladding layer is made of n-type AlGaN having an Al content of 0 or more and less than 1, and an Al content Xn of a portion of the n-type cladding layer in contact with the first barrier layer satisfies X1≦Xn<1.

The p-type cladding layer is preferably made of p-type AlGaN having an Al content of 0 or more and less than 1.

The well layers are preferably made of AlₐIn_{b}Ga_{1-a-b}N (0≦a<1, 0≦b<0.1, a+b<1). In this case, the band gap of the intermediate barrier layer having Xmin is preferably 0.2 eV or more larger than the band gap of the well layers.

### Advantageous Effect

A III nitride semiconductor light emitting device of this disclosure makes it possible to suppress the formation of cracks in an active layer and improve the light output power.

### BRIEF DESCRIPTION OF THE DRAWINGS

In the accompanying drawings,

FIG. 1 is a schematic cross-sectional view of a III nitride semiconductor light emitting device 100; and

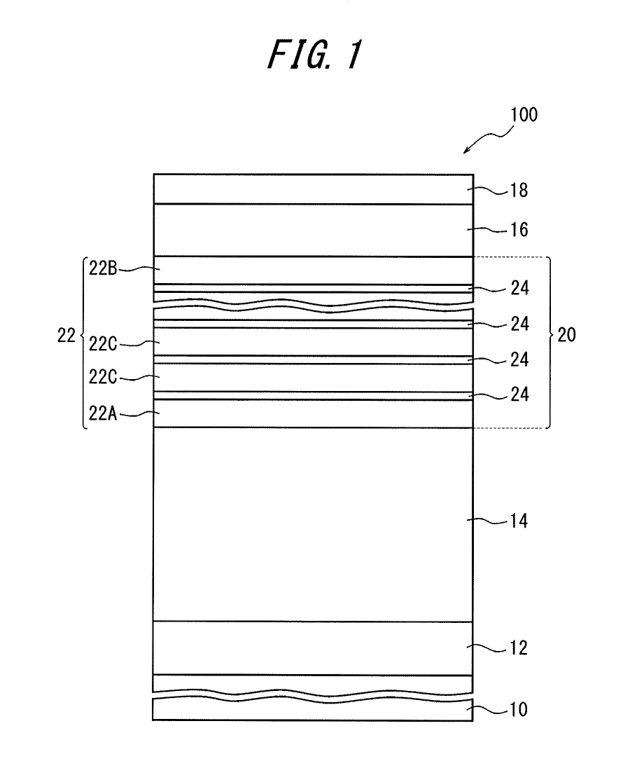

FIG. 2 is a diagram showing schematic cross-sectional views of active layers in Examples and Comparative Examples together with the III content (%) and the Al content (%) of the active layers.

### DETAILED DESCRIPTION

Embodiments of a III nitride semiconductor light emitting device of this disclosure will be described below with reference to the drawings. FIG. schematically shows a cross-sectional structure of a III nitride semiconductor light emitting device 100 which is one of the disclosed embodiments.

The III nitride semiconductor light emitting device 100 is obtained by sequentially forming a buffer layer 12 made of low temperature growth GaN or the like, an n-type cladding layer 14 made of Si-doped AlGaN or the like, an active layer 20, a p-type cladding layer 16 made of Mg-doped GaN or the like, and a p-type contact layer 18 made of Mg-doped GaN or the like having been doped more heavily than the p-type cladding layer 16, on a substrate 10 made of sapphire or the like. Accordingly, the III nitride semiconductor light emitting device 100 has a structure in which the active layer 20 is provided between the n-type cladding layer 14 and the p-type cladding layer 16.

The active layer 20 has a multiple quantum-well structure including three or more barrier layers 22 made of Al_{X}Ga_{1-X}N (0≦X<1) and two or more well layers 24 made of a III nitride semiconductor such as InGaN or AlGaN interposed between the barrier layers. Here, in this specification, the barrier layers 22 are classified as a first barrier layer 22A on the n-type cladding layer 14 side, a second barrier layer 22B on the p-type cladding layer 16 side, and one or more intermediate barrier layers 22C located between the first barrier layer 22A and the second barrier layer 22B.

A structure of this disclosure is typified by the profile of the Al content X of the barrier layers 22 made of Al_{X}Ga_{1-X}N (0≦X<1) in the active layer 20. First, the Al content X of the barrier layers 22 is larger as the barrier layer is closer to the first barrier layer 22A and the second barrier layer 22B with reference to one or more intermediate barrier layers having the lowest Al content X min of the intermediate barrier layers 22C. In other words, the Al content is increased in a stepwise fashion from the intermediate barrier layer(s) 22C having the lowest Al content toward the bottom and top barrier layers 22A and 22B of the active layer. Moreover, in this disclosure, the Al content X1 of the first barrier layer 22A, the Al content X2 of the second barrier layer 22B, and Xmin satisfy Equation (1) and Equation (2):

X2+0.01≦X1 (1), and

Xmin+0.03≦X2 (2).

In terms of improving the light output power of the III nitride semiconductor light emitting device, the inventor made various studies focused on the profile of the Al content X of the barrier layers made of Al_{X}Ga_{1-X}N (0≦X<1) in the active layer, and thus find the following. First, as compared with the case where all the barrier layers have the same Al content, the light output power is improved to some extent in the case where the Al content is increased in a stepwise fashion from a certain intermediate barrier layer(s) to the bottom and top barrier layers of the active layer while the bottom barrier layer and the top barrier layer have the same Al content. This structure is similar to one described in PTL 1.

However, the inventor newly found in further studies to improve the light emission efficiency that with the stepwise Al content profile as described above being maintained, the Al content X2 of the second barrier layer 22B on the p-type cladding layer 16 side being lower than the Al content X1 of the first barrier layer 22A on the n-type cladding layer 14 side, specifically, being (X1−0.01) or less could further improve the light output power. Moreover, no cracks were formed in the active layer.

Note that according to the studies of the inventor, when X2 was higher than X1 (Comparative Example 3), cracks were formed in the active layer, and the resulting device was unsuitable as a light emitting device.

In conventional techniques, barrier layers made of Al_{X}Ga_{1-X}N (0≦X<1) that apply tensile strains to the well layers are simply stacked, resulting in the accumulation of the strains which would induce the degradation of the crystallinity of the active layer or the formation of cracks therein. In contrast, the advantageous effects described above are considered to have been achieved because when the X2 is lower than X1, the lattice constant difference with the well layers can be reduced, preventing the degradation in the crystallinity of the active layer or the cracks therein which would occur as the number of the barrier layers increases from being induced.

When the Al content X2 of the second barrier layer 22B is excessively low, the difference between the lowest Al content Xmin of the intermediate barrier layers 22C and X2 comes to be less than 0.03. In such a case, electrons supplied through the n-type cladding layer leak from the active layer at a higher rate (carrier overflow), which limits the ratio of the carrier components that contribute to the emission with respect to the supplied power, and the leaked carriers eventually turn into heat. Accordingly, the light emission efficiency is significantly reduced, so that the light output power improving effect cannot be obtained. Therefore, Xmin+0.03≦X2 needs to be satisfied.

The substrate 10 is not limited in particular; for example, a sapphire substrate, a Si single crystal substrate, or an AlN single crystal substrate can be used. Alternatively, a template substrate may be used in which a III nitride semiconductor containing at least Al is provided on a base substrate of, for example, sapphire (Al₂O₃), Si, SiC, or GaN. Other options include a surface-nitrided sapphire substrate obtained by nitriding the surface of sapphire or a substrate with a surface made of a layer of metal nitride or a layer containing a metal oxide for chemical lift-off.

The buffer layer 12 serves to reduce dislocations or strains resulted from the lattice mismatch or thermal expansion difference between the substrate 10 and the n-type cladding layer 14, and it can be selected from known buffer layers depending on the kind of the substrate 10 and the n-type cladding layer 14. Examples of preferable materials of the buffer layer 12 include, for example, AlN, GaN, AlGaN, InGaN, and AlInGaN which are undoped. The thickness of the buffer layer 12 is preferably 0.5 μm to 20 μm. The buffer layer 12 may have a single layer structure or a layered structure like a superlattice. Note that “undoped” means not intentionally being doped with impurities, and inevitable impurities from the device or due to dispersion or the like are permissible.

The barrier layers 22 in the active layer 20 are not limited in particular as long as they are made of Al_{X}Ga_{1-X}N (0≦X<1). However, it is preferred that the Al content X including X1, X2, and Xmin ranges 0≦X≦0.7. More preferably, the Al content X ranges 0≦X≦0.15 for the composition range of the well layers where the emission peak wavelength is within the near ultraviolet range. When X is 0.7 or less, cracks are hardly formed in the active layer and a highly reliable nitride semiconductor device can be obtained.

Within the range 0≦X≦0.7, X1−X2 is preferably 0.01 or more and 0.15 or less. The difference being 0.01 or more can sufficiently suppress the carrier overflow, and the difference being 0.15 or less can sufficiently suppress the formation of cracks in the active layer.

In this specification, “the Al content gradually increases” means that the Al content of the barrier layers is increased in a stepwise fashion from a certain intermediate barrier layer(s) 22C toward the first and second barrier layers 22A and 22B such that the Al content is maintained or increased without being reduced. Accordingly, as long as the Al content X has a high-low-high profile from the first barrier layer toward the second barrier layer, the case where adjacent barrier layers have the same Al content is not excluded. However, in terms of sufficiently achieving the advantageous effects, the Al content difference between adjacent barrier layers is preferably 0.01 or more. Further, in terms of sufficiently suppressing the formation of cracks in the active layer, the Al content difference between adjacent barrier layers is preferably 0.15 or less. In addition, two or more layers of the intermediate barrier layers 22C may have Xmin.

The intermediate barrier layers 22 are preferably i-type or n-type. In particular, in terms of further improving the light output power, barrier layers on the n-type cladding layer 14 side (for example, the first barrier layer 22A and some of the intermediate barrier layers 22C on the n-type cladding layer 14 side) are preferably n-type, and barrier layers on the p-type cladding layer 16 side (for example, the second barrier layer 22B and some of the intermediate barrier layers 22C on the p-type cladding layer 16 side) are preferably i-type. As examples of n-type impurities, Si, Ge, Sn, S, O, Ti, and Zr can be given.

The well layers 24 in the active layer 20 are not limited in particular as long as they are made of a III nitride semiconductor having a smaller band gap than all the barrier layers 22. The examples of the material of the well layers 24 include InGaN, GaN, AlGaN, and AlInGaN that are i-type. The emission peak wavelength from the active layer 20 depends on the content ratio of the Group III element of the material of the well layers 24. It is particularly preferred that the well layers 24 are made of AlₐIn_{b}Ga_{1-a-b}N (0≦a<1, 0≦b<0.1, a+b<1). In that case, the emission peak wavelength is in the ultraviolet range of 197 nm to 420 nm. In particular, when a=0 and 0≦b<0.1, the emission peak wavelength is within the near ultraviolet range of 365 nm to 420 nm, whereas when b=0, the emission peak wavelength is within the ultraviolet range of 365 nm or less.

Here, the band gap E1 of the intermediate barrier layer(s) having Xmin is preferably 0.2 eV or more larger than the band gap E2 of the well layers made of AlₐIn_{b}Ga_{1-a-b}N (0≦a<1, 0≦b<0.1, a+b<1). A minimum band gap difference is necessarily ensured which prevents excessive carrier overflow between the well layers and the adjacent barrier layers in the active layer.

Note that the value of the band gap can be determined in accordance with the following formulas of Vegard's law with reference to E. F. Schubert, Light-Emitting Diodes SECOND EDITION, Cambridge University Press, 2006.

E1=3.42+2.86Xmin−Xmin(1−Xmin)

E2=3.42+2.86a−a(1−a)−2.65b−2.4b(1−b)

For example, the Al content Xmin of the barrier layer(s) made of In_{0.037}Ga_{0.963}N is found to be preferably 0.01 or more for well layers emitting a wavelength of 383 nm (3.24 eV). Note that the bandgap of the intermediate barrier layers is 0.2 eV or more larger than that of the well layers In_{0.05}Ga_{0.95}N in the following example, even when Xmin is 0. When the well layers do not contain In (b=0), the Al content Xmin is preferably 0.11 or more higher than the Al content of the well layers.

Preferably, the thickness of the barrier layers 22 is approximately 1 nm to 5 nm and that of the well layers 24 is approximately 3 nm to 10 nm. Further, the thickness of the well layers 24 is preferably smaller than that of the barrier layers 22. The total thickness of the active layer 20 can be at least 15 nm.

The n-type cladding layer 14 is not limited in particular; for example, AlGaN having an Al content of 0 or more and less than 1, doped with an n-type impurity such as Si, Ge, Sn, S, O, Ti, or Zr can be used. In that case, the n-type cladding layer 14 may be an AlGaN layer having a single composition in which the Al content does not vary in the thickness direction, or a composition gradient AlGaN layer in which the Al content is higher as in portions closer to the first barrier layer 22A in the thickness direction. On that occasion, the Al content Xn of a portion of the n-type cladding layer 14 in contact with the first barrier layer preferably satisfies X1≦Xn<1 in terms of sufficiently suppressing the formation of cracks in the active layer. It is preferred that Xn−X1 is 0 or more and 0.3 or less, and X1=Xn is more preferred. When Xn−X1 is 0.3 or less, the lattice constant difference between the n-type cladding layer and the active layer is not excessively large and the formation of cracks in the active layer can sufficiently be suppressed. When the n-type impurity concentration is approximately 5×10¹⁶/cm³ to 1×10¹⁸/cm³, sufficient conductivity can be secured with the degradation of the crystallinity being suppressed.

The p-type cladding layer 16 is not limited in particular; for example, AlGaN having an Al content of 0 or more and less than 1, doped with a p-type impurity such as Mg, Zn, Ca, Be, or Mn can be used. In that case, the Al content Xp of a portion of the p-type cladding layer in contact with the second barrier layer preferably satisfies 0≦Xp≦Xmin. With Xp being equal to or less than Xmin, the barrier inhibiting the transition of holes in the valance band becomes small. Xmin−Xp is preferably 0.01 or more and 0.3 or less. When Xmin−Xp is 0.01 or more, the overflow of electrons can sufficiently be suppressed. Whereas when it is 0.3 or less, the overflow of holes can sufficiently be suppressed. The thickness of the p-type cladding layer 16 can be approximately 10 nm to 600 nm. Note that as an example of another embodiment, although not shown, a layer having a small thickness called a p-type blocking layer having a higher Al content than the p-type cladding layer 16 may be added between the p-type cladding layer and the active layer.

The p-type contact layer 18 is not limited in particular; for example, AlGaN heavily doped with a p-type impurity may be used, which has a thickness of approximately 10 nm to 200 nm and an Al content of 0 or more and less than 1. When the p-type impurity concentration is approximately 5×10¹⁸/cm³ to 1×10²⁰/cm³, sufficient conductivity can be secured with the degradation of the crystallinity being suppressed. A graded composition or a superlattice structure may be used for the p-type cladding layer 16 and the p-type contact layer 18.

This embodiment describes an example of forming the n-type cladding layer 14 on the buffer layer 12; however, this disclosure is not limited to the structure. It is obvious that a p-type cladding layer may be formed on the buffer layer instead.

As a method for epitaxially growing the layers in this disclosure, a well-known method such as MOCVD or MBE can be used. Examples of the source gas for In include TMIn (trimethylindium); examples of the source gas for Al include TMA (trimethylaluminum); examples of the source gas for Ga include TMG (trimethylgallium); and examples of the source gas for N include ammonia. The Group III element content ratio of the layers can be adjusted by controlling the mixing ratio of TMIn, TMA, and TMG. Further, for the evaluations of the Al content, the In content, and the thickness of the layers after the epitaxial growth, a well-known method such as TEM-EDS can be used.

In this specification, the III nitride semiconductor such as AlGaN, InGaN, or GaN may contain other Group III elements up to 1% in total. Further, those layers may contain a slight amount of impurities such as Si, H, O, C, Mg, As, or P.

The thus obtained III nitride semiconductor light emitting device 100 can be made capable of being powered, by forming an n-side electrode electrically connected to the n-type cladding layer 14 and a p-side electrode electrically connected to the p-type cladding layer 16. For example, a light emitting device having a lateral structure can be formed by partly removing the layers of the p-type contact layer 18, the p-type cladding layer 16, and the active layer 20 to expose the n-type cladding layer 14; providing an n-side electrode on the exposed n-type cladding layer 14; and providing a p-side electrode on the p-type contact layer 18.

The III nitride semiconductor light emitting device of this disclosure will be described in more detail below using examples. However, this disclosure is not limited to the following examples.

### EXAMPLES

### Example 1

A low temperature growth buffer layer (thickness: 60 nm) made of GaN was epitaxially grown on a sapphire substrate (thickness: 430 μm) at a furnace temperature of 1070° C. On this buffer layer, as an n-type cladding layer, a composition gradient layer (thickness: 4 μM, dopant: Si, dopant concentration: 4×10¹⁸/cm³) made of n-type Al_{X}Ga_{1-X}N was epitaxially grown, which has the Al content X that continuously varies from 0 to 0.12 in the crystal growth direction. Accordingly, in this example, Xn=0.12.

Next, a first barrier layer (thickness: 9 nm) made of Al_{0.12}Ga_{0.88}N, a well layer (thickness: 2 nm) made of In_{0.05}Ga_{0.95}N, a first intermediate barrier layer (thickness: 9 nm) made of Al_{0.09}Ga_{0.91}N, a well layer (thickness: 2 nm) made of In_{0.05}Ga_{0.95}N, a second intermediate barrier layer (thickness: 9 nm) made of Al_{0.06}Ga_{0.94}N, a well layer (thickness: 2 nm) made of In_{0.05}Ga_{0.95}N, a third intermediate barrier layer (thickness: 9 nm) made of Al_{0.03}Ga_{0.97}N, a well layer (thickness: 2 nm) made of In_{0.05}Ga_{0.95}N, a fourth intermediate barrier layer (thickness: 9 nm) made of Al_{0.03}Ga_{0.97}N, a well layer (thickness: 2 nm) made of In_{0.05}Ga_{0.95}N, a fifth intermediate barrier layer (thickness: 9 nm) made of Al_{0.06}Ga_{0.94}N, a well layer (thickness: 2 nm) made of In_{0.05}Ga_{0.95}N, and a second barrier layer (thickness: 9 nm) made of Al_{0.09}Ga_{0.91}N were epitaxially grown sequentially on the n-type cladding layer, thereby forming an active layer having a multiple quantum-well structure in which the barrier layers (seven layers in total) and the well layers (six layers in total) are alternately provided. Note that the total four layers consisting of the first barrier layer and the first to third intermediate barrier layers were doped with Si to obtain n-type layers (dopant concentration: 3×10¹⁸/cm³).

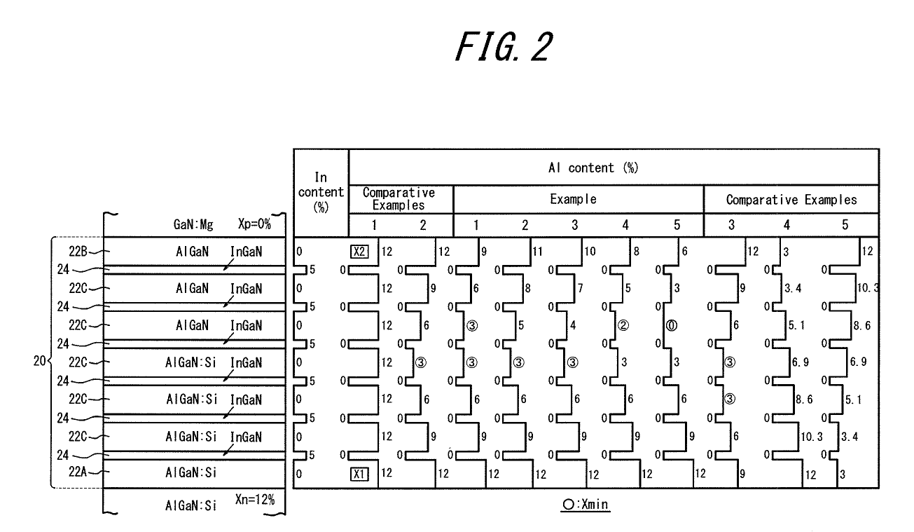

FIG. 2 shows the layer structure of the active layer, and the In content (%) and the Al content (%) of the active layer. Further, Table 1 shows the profile of the Al content (%) of the seven layers of the barrier layers in the order from the n-type cladding layer side to the p-type cladding layer side. Thus, in this example, the third intermediate barrier layer and the fourth intermediate barrier layer had the minimum Al content Xmin=0.03, and the Al content of the barrier layers gradually increased toward the first barrier layer and the second barrier layer with reference to the third and fourth intermediate barrier layers. The first barrier layer Al content X1=0.12, and the second barrier layer Al content X2=0.09. Accordingly, the relations X2+0.01≦X1 and Xmin+0.03≦X2 are satisfied.

A p-type cladding layer made of p-type GaN (Xp=0, thickness: 200 nm, dopant: Mg, dopant concentration: 1×10¹⁸/cm³) was epitaxially grown on the active layer, and a p-type contact layer made of p-type GaN (thickness: 20 nm, dopant: Mg, dopant concentration: 3×10¹⁹/cm³) was then epitaxially grown thereon. Thus, a III nitride semiconductor light emitting device of Example 1 was fabricated.

MOCVD was used as the method for growing the layers. TMIn (trimethylindium) was used as the source gas for In; TMA (trimethylaluminum) the source gas for Al; TMG (trimethylgallium) the source gas for Ga; and ammonia the source gas for N. Nitrogen and hydrogen were used for a carrier gas. The supply ratio between TMA and TMG was controlled thereby adjusting the Al content of the AlGaN layers, and the supply ratio between TMIn and TMG was controlled thereby adjusting the In content of the InGaN layers. The growth conditions for the n-type cladding layer, the active layer, the p-type cladding layer, and the p-type contact layer were pressure: 10 kPa and temperature: 1150° C. The growth method described above also applies to other Examples and Comparative Examples. Note that the values calculated by quantitatively analyzing the Al and In elements of the vicinity of the center of the layers based on the measurements using a TEM-EDS system (INCA v. 4.07, manufactured by Oxford Instruments plc) on the cross section of the substrate center exposed by cleaving the grown substrate were used as the values of the Al content and In content of each layer.

### Examples 2 to 5 and Comparative Examples 1 to 5

III nitride semiconductor light emitting devices of Examples 2 to 5 and Comparative Examples 1 to 5 were fabricated in the same manner as Example 1 except that the Al content of the seven layers of the barrier layers were as shown in FIG. 2 and Table 1.

In Examples 2 to 5, the third intermediate barrier layer or the fourth intermediate barrier layer had the minimum Al content and the Al content of the barrier layers are gradually increased toward the first barrier layer and the second barrier layer with reference to the third or fourth intermediate barrier layer. Further, the Al content X1 of the first barrier layer, the Al content X2 of the second barrier layer, and Xmin satisfy the relations X2+0.01≦X1 and Xmin+0.03≦X2.

Here Comparative Example 1 is an example in which the Al content of all the seven layers of the barrier layers was 0.12. In Comparative Example 2, the third intermediate barrier layer had the minimum Al content Xmin=0.03, and the Al content of the barrier layers was gradually increased toward the first barrier layer and the second barrier layer with reference to the third intermediate barrier layer. However, X1=X2=0.12 does not satisfy the relation X2+0.01≦X1. Comparative Example 3 is an example in which the Al content profile is opposite to that of Example 1. Specifically, the second intermediate barrier layer and the third intermediate barrier layer had the minimum Al content Xmin=0.03, and the Al content of the barrier layers gradually increased by 0.03 per layer toward the first barrier layer and the second barrier layer with reference to the second and third intermediate barrier layers. However, X1=0.09 and X2=0.12, hence X2>X1. Comparative Example 4 is an example in which the Al content of the layers is sequentially reduced from the first barrier layer to the second barrier layer (X1=0.12→X2=0.03). Comparative Example 5 is an example in which the Al content of the layers is sequentially increased from the first barrier layer to the second barrier layer (X1=0.03→X2=0.12).

(Evaluation 1: Light Output Power Po)

For each sample of Examples and Comparative Examples, the epitaxially grown surface was scribed with a diamond pen; indium dots were physically pressed against a point where the n-type cladding layer was exposed and a point on the p-type contact layer 1.5 mm distant from the exposed point. The thus formed two points were used as an n-type electrode and a p-type electrode. Then, probes were put on those points, light obtained after current application was output from the sapphire substrate side, and the light was guided to a multi-channel spectrometer manufactured by Hamamatsu Photonics K.K. through optical fiber. The peak intensity of the spectrum was converted to W (watts) to find the light output power Po. The results are shown in Table 1. Note that in each of Examples and Comparative Examples, In_{0.05}Ga_{0.95}N was used for the well layers, so that the emission peak wavelength from the active layer was 385 nm to 390 nm.

(Evaluation 2: Presence or Absence of Cracks)

Each sample of Examples and Comparative Examples was examined to determine whether cracks were formed in the active layer by the following method. The morphology of each sample was observed using an optical microscope with the p-type contact layer being on the upper side to examine the presence or otherwise of cracks in a 1 mm² square area in the center portion of the wafer. The results are shown in Table 1.

TABLE 1

| Al content (%) profile | | | | |
|---|---|---|---|---|
| of Barrier layers | | | Light output | |
| n side | middle | p side | power Po | Cracks |
| X1 | | X2 | (mW) | formed |

| | | | | | | | | | |
|---|---|---|---|---|---|---|---|---|---|
| Comparative Example 1 | 12 | 12 | 12 | 12 | 12 | 12 | 12 | 2.00 | Yes |
| Comparative Example 2 | 12 | 9 | 6 | 3 | 6 | 9 | 12 | 4.08 | No |
| Example 1 | 12 | 9 | 6 | 3 | 3 | 6 | 9 | 5.79 | No |
| Example 2 | 12 | 9 | 6 | 3 | 5 | 8 | 11 | 5.68 | No |
| Example 3 | 12 | 9 | 6 | 3 | 4 | 7 | 10 | 6.31 | No |
| Example 4 | 12 | 9 | 6 | 3 | 2 | 5 | 8 | 5.32 | No |
| Example 5 | 12 | 9 | 6 | 3 | 0 | 3 | 6 | 4.78 | No |
| Comparative Example 3 | 9 | 6 | 3 | 3 | 6 | 9 | 12 | 5.01 | Yes |
| Comparative Example 4 | 12 | 10.3 | 8.6 | 6.9 | 5.1 | 3.4 | 3 | 0.64 | No |
| Comparative Example 5 | 3 | 3.4 | 5.1 | 6.9 | 8.6 | 10.3 | 12 | 2.74 | No |

As shown in Table 1, in Comparative Examples 1, 4, and 5, the light output power Po was very low, and in Comparative Example 1, cracks were also formed in the active layer. As in Comparative Example 2, when the third intermediate barrier layer had the minimum Al content and the Al content of the barrier layers was gradually increased toward the n-type cladding layer and the p-type cladding layer, the light output power was improved to some extent yet the improvement was insufficient. On the other hand, as in Examples 1 to 5, when the Al content of the barrier layer in contact with the p-type cladding layer was made lower than that of the barrier layer in contact with the n-type cladding layer while any of the intermediate barrier layer(s) had the minimum Al content and the Al content of the barrier layers was gradually increased toward the n-type cladding layer and the p-type cladding layer, certainly no cracks were formed in the active layer, and the light output power was further improved. Conversely, in the case of Comparative Example 3 where the Al content of the barrier layer in contact with the p-type cladding layer was made higher than that of the n-type cladding layer, relatively high light output power was achieved; however, cracks were formed in the active layer and the obtained device was not suitable as a light emitting device.

### INDUSTRIAL APPLICABILITY

A III nitride semiconductor light emitting device of this disclosure makes it possible to suppress the formation of cracks in an active layer and improve the light output power.

### REFERENCE SIGNS LIST

100: III nitride semiconductor light emitting device
10: Substrate
12: Buffer layer
14: n-type cladding layer
16: p-type cladding layer
18: p-type contact layer
20: Active layer
22: Barrier layer
22A: First barrier layer
22B: Second barrier layer
22C: Intermediate barrier layer
24: Well layer

1. A III nitride semiconductor light emitting device having an active layer between an n-type cladding layer and a p-type cladding layer, wherein
the active layer has a multiple quantum-well structure including three or more barrier layers made of Al_{X}Ga_{1-X}N (0≦X<1) including a first barrier layer on the n-type cladding layer side, a second barrier layer on the p-type cladding layer side, and one or more intermediate barrier layers located between the first and second barrier layers; and two or more well layers made of a III nitride semiconductor interposed between the barrier layers,
the Al content X of the barrier layers is larger as the barrier layer is closer to the first barrier layer and the second barrier layer with reference to one or more of the intermediate barrier layers having the lowest Al content X min of the intermediate barrier layers, and
an Al content X1 of the first barrier layer, an Al content X2 of the second barrier layer, and the Xmin satisfy the relations represented by the Equation (1) and Equation (2):
X2+0.01≦X1 (1), and
Xmin+0.03≦X2 (2).

2. The III nitride semiconductor light emitting device according to claim 1, wherein the n-type cladding layer is made of n-type AlGaN having an Al content of 0 or more and less than 1, and an Al content Xn of a portion of the n-type cladding layer in contact with the first barrier layer satisfies X1≦Xn<1.

3. The III nitride semiconductor light emitting device according to claim 1, wherein the p-type cladding layer is made of p-type AlGaN having an Al content of 0 or more and less than 1.

4. The III nitride semiconductor light emitting device according to claim 1, wherein the well layers are made of AlₐIn_{b}Ga_{1-a-b}N (0≦a<1, 0≦b<0.1, a+b<1).

5. The III nitride semiconductor light emitting device according to claim 4, wherein the band gap of the intermediate barrier layer having the Xmin is 0.2 eV or more larger than the band gap of the well layers.

6. The III nitride semiconductor light emitting device according to claim 2, wherein the p-type cladding layer is made of p-type AlGaN having an Al content of 0 or more and less than 1.

7. The III nitride semiconductor light emitting device according to claim 2, wherein the well layers are made of AlₐIn_{b}Ga_{1-a-b}N (0≦a<1, 0≦b<0.1, a+b<1).

8. The III nitride semiconductor light emitting device according to claim 3, wherein the well layers are made of AlₐIn_{b}Ga_{1-a-b}N (0≦a<1, 0≦b<0.1, a+b<1).

9. The III nitride semiconductor light emitting device according to claim 6, wherein the well layers are made of AlₐIn_{b}Ga_{1-a-b}N (0≦a<1, 0≦b<0.1, a+b<1).

10. The III nitride semiconductor light emitting device according to claim 7, wherein the band gap of the intermediate barrier layer having the Xmin is 0.2 eV or more larger than the band gap of the well layers.

11. The III nitride semiconductor light emitting device according to claim 8, wherein the band gap of the intermediate barrier layer having the Xmin is 0.2 eV or more larger than the band gap of the well layers.

12. The III nitride semiconductor light emitting device according to claim 9, wherein the band gap of the intermediate barrier layer having the Xmin is 0.2 eV or more larger than the band gap of the well layers.
